(19) United States
(12) Patent Application Publication
(10) Pub. No.: US 2025/0266276 A1
(43) Pub. Date: Aug. 21, 2025

(54) Transport Facility

(71) Applicant: Daifuku Co., Ltd., Osaka-shi (JP)

(72) Inventor: Yosuke Fujiwara, Komaki-shi (JP)

(21) Appl. No.: 19/056,867

(22) Filed: Feb. 19, 2025

(30) Foreign Application Priority Data
Feb. 20, 2024 (JP) 2024-023704

(51) Int. Cl. H01L 21/67; H01L 21/677

(52) U.S. Cl. CPC H01L 21/67288; H01L 21/67715; H01L 21/67733

(57) ABSTRACT

A transport facility includes an information collection device mounted in a transport vehicle, a mobile body that moves separately from the transport vehicle, and a communication system. The information collection device includes an abnormality information acquisition unit that acquires, in response to the occurrence of an abnormality in the transport vehicle, abnormality information including at least one of abnormality content information, pre-abnormality occurrence information, and post-abnormality occurrence information, and a first communication unit that transmits the abnormality information. The mobile body includes a second communication unit that communicates with the first communication unit and receives the abnormality information, not via the first communication system, and a third communication unit that gives an administrator terminal an abnormality occurrence notification, which is a notification of the occurrence of an abnormality.

### CROSS-REFERENCE TO RELATED APPLICATION

This application claims priority to Japanese Patent Application No. 2024-023704 filed Feb. 20, 2024, the disclosure of which is hereby incorporated by reference in its entirety.

### BACKGROUND OF THE INVENTION

### 1. Field of the Invention

The present invention relates to a transport facility that includes a transport vehicle configured to transport an item to be transported.

### 2. Description of Related Art

The invention disclosed in JP 6504266B is an example of this type of transport facility. The invention disclosed in JP 6504266B provides a controller (50) that causes a transport vehicle (20) to transport an item to be transported (90) by communicating with the transport vehicle (20). Commonly, the controller communicates with the transport vehicle in this type of transport facility to exchange various types of information.

Information transmitted and received between the controller and the transport vehicle may include abnormality information. If, for example, the transport vehicle is stopped due to the occurrence of an abnormality (abnormal stop), it may impede the traveling of other normal transport vehicles following the stopped transport vehicle. In this case, the abnormality in one transport vehicle may affect the entire facility. In the case where, for example, an abnormality occurs in a transport vehicle in a transport facility in which a controller controls the transport vehicle as in JP 6504266B, typically, information related to the abnormality is notified from the transport vehicle to the controller, and then from the controller to an administrator terminal. This allows an administrator or the like to ascertain the abnormality occurring in the transport vehicle. However, if communication between the controller and the transport vehicle is faulty in the first place, information related to the abnormality occurring in the transport vehicle is naturally not notified to the administrator terminal, and the administrator is unable to ascertain the occurrence of the abnormality.

### SUMMARY OF THE INVENTION

In view of the foregoing situation, there is a need to realize a technology capable of properly ascertaining an abnormality in a transport vehicle.

A technology for solving the above issue is as follows.

A transport facility includes:
a transport vehicle configured to transport an item to be transported;
an information collection device mounted in the transport vehicle;
a mobile body configured to move separately from the transport vehicle; and
a communication system configured to enable communication between the transport vehicle and a transport control device configured to control the transport vehicle,

wherein the information collection device includes:
an abnormality information acquisition unit configured to acquire, in response to an occurrence of an abnormality in the transport vehicle, abnormality information including at least one of: (i) abnormality content information indicating content of the abnormality; (ii) pre-abnormality occurrence information indicating a state of the transport vehicle before the occurrence of the abnormality; and (iii) post-abnormality occurrence information indicating a state of the transport vehicle after the occurrence of the abnormality; and
a first communication unit configured to transmit the abnormality information, and

the mobile body includes:
a second communication unit configured to communicate with the first communication unit and receive the abnormality information, not via the communication system; and
a third communication unit configured to give an abnormality occurrence notification being a notification of the occurrence of the abnormality, to an administrator terminal capable of being viewed by an administrator administering the transport vehicle.

With this configuration, the mobile body can acquire, in response to the occurrence of an abnormality in a transport vehicle, the abnormality information indicating a cause of the abnormality in the transport vehicle and the state of the transport vehicle before and after the abnormality, and can give the abnormality occurrence notification to the administrator terminal. The administrator can thus quickly ascertain that an abnormality has occurred in the transport vehicle. Further, with this configuration, the mobile body can receive the abnormality information, not via the communication system. Even if communication cannot be performed normally via the communication system due to, for example, the abnormality occurring in the transport vehicle, the abnormality occurrence notification can thus be properly given to the administrator terminal. The administrator can therefore quickly ascertain the abnormality occurring in the transport vehicle regardless of the state of the communication system. As described above, this configuration allows an abnormality in the transport vehicle to be ascertained properly.

Further features and advantages of the technology according to the present disclosure will become more apparent from the following description of illustrative and non-limiting embodiments with reference to the drawings.

### BRIEF DESCRIPTION OF THE DRAWINGS

FIG. 1 is a schematic diagram of a transport facility.

FIG. 2 shows a transport vehicle and a mobile body.

FIG. 3 shows a system configuration of the transport facility.

FIG. 4 is a flowchart of a procedure that starts when an abnormality occurs and ends when restoration processing is performed.

### DESCRIPTION OF THE INVENTION

A transport facility is a facility that includes a transport vehicle configured to transport an item to be transported. Hereinafter, an embodiment of the transport facility will be described with reference to the drawings.

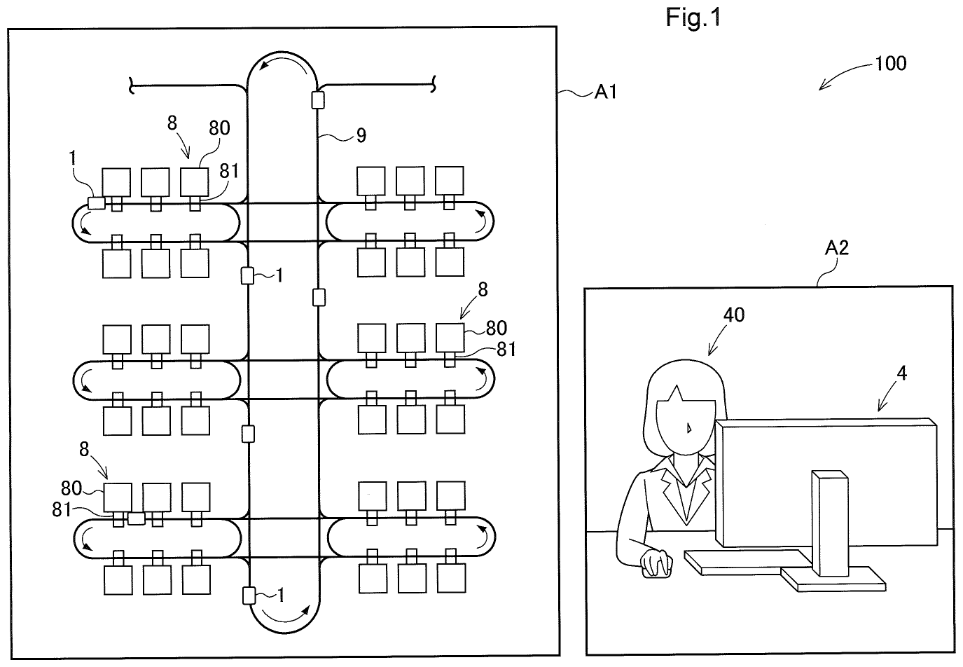

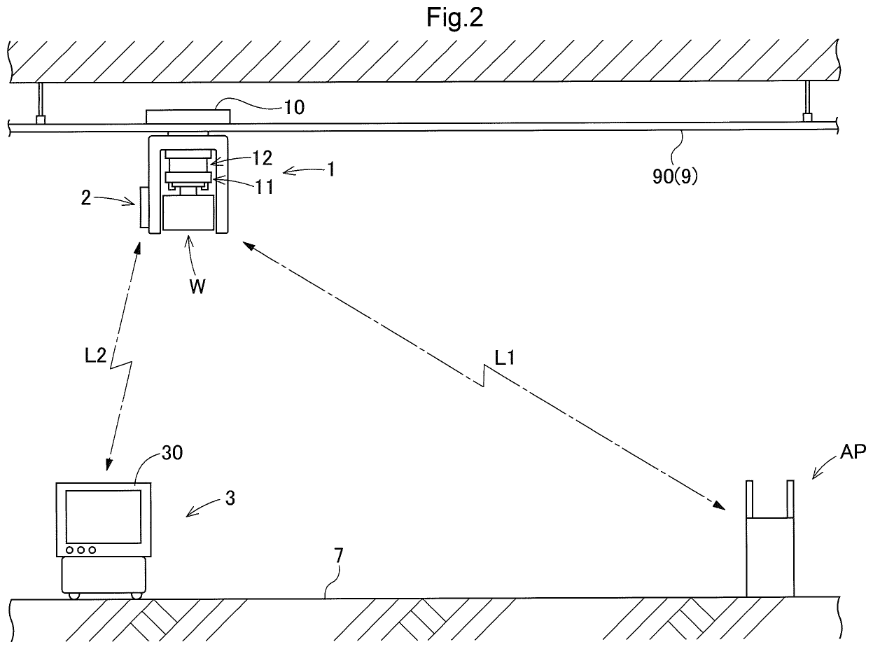

As shown in FIG. 1, a transport facility 100 in the present embodiment includes a transport room A1 in which transport vehicles 1 transport items to be transported W (see FIG. 2), and an administration room A2 in which an administrator terminal 4, which is operated by an administrator 40 (also referred to as a “worker 40”), is installed. The administration room A2 is provided outside the transport room A1. The administration room A2 and the transport room A1 allow the administrator 40 to come and go. Note that the administrator terminal 4 may be a mobile terminal that can be carried outside the administration room A2.

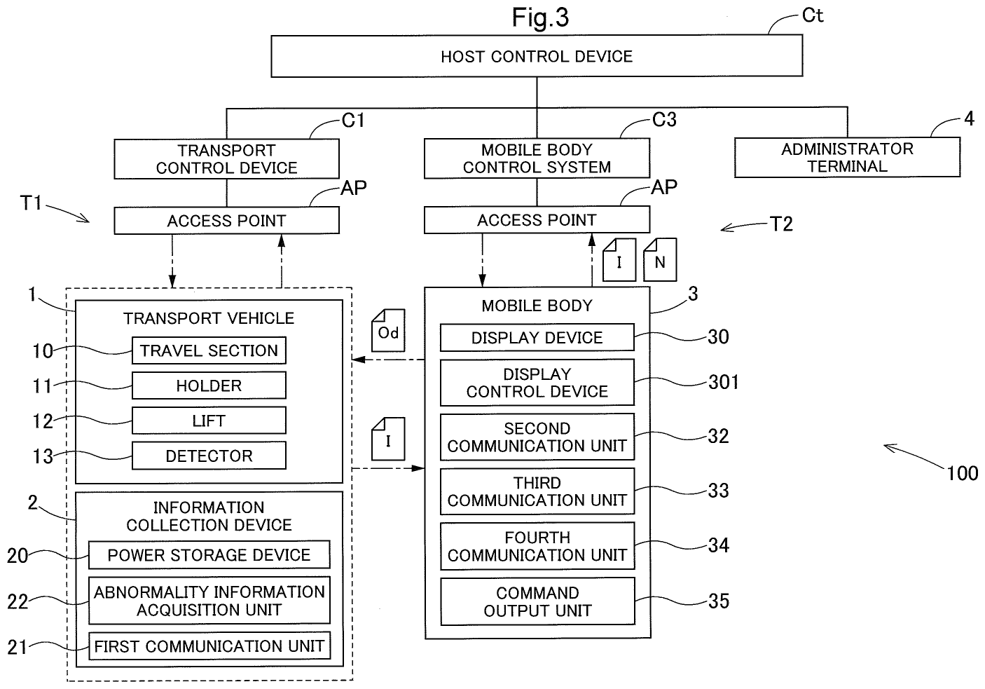

The transport facility 100 includes a plurality of transport vehicles 1 that travel along a movement route 9, and a transport control device C1 (see FIG. 3) that controls the transport vehicles 1. The movement route 9 is provided in the transport room A1.

The movement route 9 in the present embodiment is constituted by rails 90 (see FIG. 2) provided near the ceiling. The transport vehicle 1 is configured as a so-called overhead hoist transport and travels on the rails 90 along the movement route 9.

A plurality of transfer target points 8 are provided along the movement route 9. The transfer target points 8 include those positioned below the movement route 9. Each transport vehicle 1 transfers an item to be transported W (see FIG. 2) to and from a corresponding one of the transfer target points 8 by raising and lowering the item to be transported W.

Each of the plurality of transport vehicles 1 receives a transport command from the aforementioned transport control device C1 and executes a task corresponding to the transport command. The transport command includes, for example, information regarding a transport source and a transport destination of the item to be transported W. The transport vehicle 1 that has received the transport command transports the item to be transported W from the transport source to the transport destination. The transport source and the transport destination include the aforementioned transfer target points 8.

The transport facility 100 handles various types of items to be transported W. The transport facility 100 in this example is used in a semiconductor manufacturing plant. Thus, the items to be transported W are, for example, substrate containers (so-called FOUP: Front Opening Unified Pod) that contain substrates (wafers, panels etc.), reticle containers (so-called reticle pods) that contain reticles, or magazines and trays. In this case, each transport vehicle 1 transports an item to be transported W, such as a substrate container or a reticle container, along the movement route 9 between processes.

Each transfer target point 8 in the present embodiment includes a processing device 80 that performs processing for an item to be transported W, and a placement table 81 adjacent to the processing device 80. “Processing for an item to be transported” refers to processing for an item (a substrate, a reticle etc.) contained in the item to be transported W serving as a container. Each transport vehicle 1 receives from the placement table 81 an item to be transported W that has been processed by the processing device 80, or delivers to the placement table 81 an item to be transported W that has not been processed by the processing device 80. Note that the processing device 80 performs various types of processing, such as thin film formation, photolithography, and etching.

As shown in FIG. 2, the transport vehicle 1 includes a travel section 10 that travels along the rails 90 constituting the movement route 9, and a holder 11 for holding the item to be transported W. This allows the transport vehicle 1 to transport the item to be transported W and transfer the item to be transported W to and from the transfer target point 8. The transport vehicle 1 in the present embodiment includes a lift 12 that raises and lowers the holder 11. This allows the transport vehicle 1 to transfer the item to be transported W to and from the transfer target point 8 positioned below the movement route 9.

Here, an abnormality may occur in the transport vehicle 1. An abnormal state of the transport vehicle 1 may be a state in which normal operations of the transport vehicle 1 cannot be maintained, or a state in which maintaining normal operations is not proper. Examples of abnormalities in the transport vehicle 1 itself may include operational abnormalities in the travel section 10, operational abnormalities in the holder 11, and operational abnormalities in the lift 12. Examples of abnormalities related to the transport vehicle 1 may include abnormalities in the item to be transported W held by the transport vehicle 1 (e.g., in the case of a FOUP, its lid is not completely closed), and the presence of an obstacle around the movement route 9. Hereinafter, these various abnormalities may also be referred to simply as “abnormalities”.

In response to this type of abnormality, in many cases the transport vehicle 1 typically gives a notification of the abnormality. A higher-level control system or the administrator 40 that receives the notification of the abnormality will identify the cause of the abnormality and take measures to address the abnormality.

However, even if an abnormality has occurred, the notification of the abnormality from the transport vehicle 1 may not be properly transmitted to the higher-level control system or the administrator 40 if the communication system is not functioning normally. In this case, the administrator 40 cannot ascertain the abnormality occurring in reality.

The transport facility 100 according to the present disclosure includes an information collection device 2 mounted in each transport vehicle 1, and a mobile body 3 that moves separately from the transport vehicles 1. The information collection device 2 collects information regarding abnormalities. The mobile body 3 acquires information from the information collection device 2, and, in the event of an abnormality, gives a notification of the abnormality in place of the transport vehicle 1. This makes it possible to properly give a notification of an abnormality even if a communication system involved in the transport vehicle 1 is not normally functioning. The details are described below.

As shown in FIG. 3, the transport facility 100 includes a host control device Ct that centrally manages each functional unit within the facility, the transport control device C1 that controls the transport vehicle 1, a mobile body control system C3 that controls the mobile body 3, and the administrator terminal 4. The host control device Ct, the transport control device C1, the mobile body control system C3, and the administrator terminal 4 are communicably connected to each other in a wired or wireless manner. Note that the mobile body control system C3 may be constituted by a single control device, or may include control devices (not shown) mounted in a plurality of respective mobile bodies 3.

The transport facility 100 includes a first communication system T1 for communication between the transport control device C1 and the transport vehicle 1. The transport facility 100 in the present embodiment includes a second communication system T2 for communication between the mobile body control system C3 and the mobile body 3. Note that the first communication system T1 in the present embodiment corresponds to the “communication system”.

As shown in FIG. 3, the transport control device C1 and the transport vehicle 1 communicate with each other via an access point AP (see also FIG. 2). Communication between the transport control device C1 and the access point AP is realized in a wired or wireless manner. In this example, the access point AP and the transport vehicle 1 communicate wirelessly. For example, Wi-Fi (registered trademark) communication is performed therebetween. The first communication system T1 is thus constructed by the form of communication between the transport control device C1 and the transport vehicle 1 via the access point AP. Although detailed illustration is omitted, access points APs are provided at a plurality of locations in the transport room A1 (see FIG. 1).

The mobile body control system C3 and the mobile body 3 communicate with each other via the access point AP. Communication between the mobile body control system C3 and the access point AP is realized in a wired or wireless manner. In this example, the access point AP and the mobile body 3 communicate wirelessly. For example, Wi-Fi communication is performed therebetween. The second communication system T2 is thus constructed by the form of communication between the mobile body control system C3 and the mobile body 3 via the access point AP.

The transport vehicle 1 includes a detector 13 that detects abnormalities. The detector 13 in the present embodiment detects abnormalities related to each functional unit included in the transport vehicle 1. For example, the detector 13 detects various abnormalities, such as abnormalities related to the travel section 10, abnormalities related to the holder 11, and abnormalities related to the lift 12.

Abnormalities related to the travel section 10 include malfunctions of wheels of the travel section 10. For example, in a mode in which the current position of the transport vehicle 1 is recognized based on the number of rotations of the wheels of the travel section 10, the wheels spinning on the rails 90 will make the current position of the transport vehicle 1 recognized by the control different from the actual current position of the transport vehicle 1.

Abnormalities related to the holder 11 include malfunctions of the holder 11 as well as abnormalities occurring in the item to be transported W, which is an object being held. For example, the lid of a FOUP as an item to be transported W being not completely closed is an abnormality related to the holder 11.

Abnormalities related to the lift 12 include malfunctions of a belt of the lift 12. For example, abnormalities related to the lift 12 include the belt of the lift 12 being caught and unable to move, and an obstacle present in a movement path of the holder 11 being raised and lowered by the lift 12.

The information collection device 2 includes: an abnormality information acquisition unit 22 that acquires, in response to the occurrence of an abnormality in the transport vehicle 1, abnormality information I that includes at least one of abnormality content information indicating the content of the abnormality, pre-abnormality occurrence information indicating the state of the transport vehicle 1 before the occurrence of the abnormality, and post-abnormality occurrence information indicating the state of the transport vehicle 1 after the occurrence of the abnormality; and a first communication unit 21 that transmits the abnormality information I.

The abnormality content information is information indicating each type of the aforementioned abnormalities. The pre-abnormality occurrence information may include logs or the like that indicate the state of each part of the transport vehicle 1 for a certain period of time before the occurrence of the abnormality. The post-abnormality occurrence information may include logs or the like that indicate the current state of each part of the transport vehicle 1 after the occurrence of the abnormality. The abnormality information I includes at least one of the abnormality content information, the pre-abnormality occurrence information, and the post-abnormality occurrence information.

The abnormality information acquisition unit 22 in the present embodiment acquires the abnormality information I from the detector 13 of the transport vehicle 1. With the above configuration, the abnormality information I indicating an abnormality in the transport vehicle 1 is collected by the information collection device 2 and transmitted to the outside by the first communication unit 21 of the information collection device 2. Accordingly, the abnormality information I can be transmitted to the outside via a communication path separate from the first communication system T1.

The information collection device 2 in the present embodiment includes a power storage device 20 and operates even when no power is supplied from the transport vehicle 1. This allows the information collection device 2 to operate properly regardless of the content of the abnormality that has occurred in the transport vehicle 1. For example, the power storage device 20 may be charged using regenerative braking of the transport vehicle 1, or may be charged in advance or periodically by using a charging device separate from the transport vehicle 1.

The mobile body 3 travels on a floor surface 7 (see also FIG. 2), and is configured as a so-called AMR (Autonomous Mobile Robot) in the present embodiment. The mobile body 3 includes a second communication unit 32 that communicates with the first communication unit 21, not via the first communication system T1, to receive the abnormality information I, and a third communication unit 33 that gives an abnormality occurrence notification N, which is a notification of the occurrence of an abnormality, to the administrator terminal 4 that can be viewed by the administrator 40 (see FIG. 1) who administers the transport vehicle 1. This enables the abnormality occurrence notification N to be given to the administrator terminal 4 and enables the administrator 40 to ascertain the occurrence of the abnormality. The second communication unit 32 and the third communication unit 33 may be the same or different in terms of hardware or software.

The abnormality occurrence notification N in the present embodiment includes, in addition to information indicating the occurrence of an abnormality, location-related information related to the location where the abnormality occurred and, if the abnormality information I includes the abnormality content information, also includes this abnormality content information. The location-related information is information indicating the current position of the abnormal transport vehicle 1. However, the location-related information may also include identification information regarding the transport vehicle 1, and may also include current position information and identification information regarding the mobile body 3.

The first communication unit 21 of the information collection device 2 and the second communication unit 32 of the mobile body 3 in the present embodiment perform short-range wireless communication. For example, Bluetooth (registered trademark) can be used for the short-range wireless communication. Note that Wi-Fi communication can also be used.

In the present embodiment, a second communicable distance L2, which is the distance at which the first communication unit 21 (information collection device 2) and the second communication unit 32 (mobile body 3) can communicate with each other, is shorter than a first communicable distance L1, which is the distance at which the transport vehicle 1 and the first communication system T1 (access point AP) can communicate with each other, as shown in FIG. 2. Further, the mobile body control system C3 causes the mobile body 3 to patrol an area corresponding to the movement route 9 of the transport vehicles 1. The “area corresponding to the movement route 9” is set, for example, to an area such that the distance from the area to the movement route 9 (specifically, the movement path of the transport vehicle 1 along the movement route 9) is less than or equal to the second communicable distance L2.

The mobile body control system C3 in the present embodiment causes the mobile body 3 to patrol the floor surface 7 of the transport room A1 (see FIG. 1). If the mobile body 3 discovers a transport vehicle 1 that is recognized as experiencing an abnormality through the patrol or in response to a command from the mobile body control system C3, the mobile body 3 approaches the transport vehicle 1 to a distance (second communicable distance L2) at which the mobile body 3 can communicate therewith. The mobile body 3 then communicates with the information collection device 2 mounted in the transport vehicle 1 and acquires the abnormality information I.

Here, restoration processing is required to enable the transport vehicle 1 experiencing an abnormality to return to normal operation.

The mobile body 3 in the present embodiment also includes a fourth communication unit 34 that communicates with each transport vehicle 1, and a command output unit 35 that communicates with the transport vehicle 1 via the fourth communication unit 34 and outputs an operation command Od to the transport vehicle 1, as shown in FIG. 3. This allows the mobile body 3 to urge the transport vehicle 1 to take some type of operation. The operation command Od in the present embodiment includes a restoration operation command for restoring the transport vehicle 1 from the abnormal state. This enables the abnormal transport vehicle 1 to return to the normal operation.

The restoration processing in the present embodiment includes automatic restoration processing. The automatic restoration processing is processing for restoring the transport vehicle 1 without the involvement of the worker 40 who operates the administrator terminal 4.

The automatic restoration processing is executed on the condition that the content of the abnormality that has occurred in the transport vehicle 1 is clear and the importance of the abnormality content is low. It is preferable that the importance of the abnormality content is set in advance for each abnormality type. The importance of the abnormality content is included in the abnormality information I. This abnormality information I is updated daily. The abnormality information I can be updated by remote distribution from the administrator terminal 4 to the mobile body 3, thereby allowing the restoration processing to be updated remotely.

In the present embodiment, the command output unit 35 generates a restoration operation command and outputs this restoration operation command to the transport vehicle 1. For example, the command output unit 35 has an automatic restoration program that determines the content of the restoration operation command based on the abnormality information I received by the second communication unit 32. The command output unit 35 then outputs a restoration operation command (operation command Od) with the content determined by the automatic restoration program to the transport vehicle 1. The automatic restoration processing is executed in this manner. In the automatic restoration processing, if, for example, an abnormality occurs that prevents the transport vehicle 1 from recognizing its own position, the command output unit 35 transmits to the transport vehicle 1 information regarding its position. Also, if an abnormality occurs that prevents the holder 11 of the transport vehicle 1 from properly holding the item to be transported W, the command output unit 35 transmits to the transport vehicle 1 a signal for causing the holder 11 to redo the holding operation. If an abnormality occurs in the detector 13 of the transport vehicle 1, the command output unit 35 transmits to the transport vehicle 1 a signal for restarting the detector 13. Executing the above-described automatic restoration processing can reduce the degree by which the worker 40 is involved in the restoration work.

The restoration processing in the present embodiment includes remote restoration processing. The remote restoration processing is processing for remotely restoring the transport vehicle 1 at the discretion of the worker 40 who operates the administrator terminal 4.

The remote restoration processing is executed on the condition that the content of the abnormality that has occurred in the transport vehicle 1 is clear and the importance of the abnormality content is middle.

In the present embodiment, a restoration operation command generated by the administrator terminal 4 is transmitted to the mobile body 3 via the mobile body control system C3. This restoration operation command (operation command Od) is output from the mobile body 3 to the transport vehicle 1. The remote restoration processing is executed in this manner. Executing the remote restoration processing can relatively reduce the degree by which the worker 40 is involved in the restoration work.

The restoration processing in the present embodiment includes on-site restoration processing. The on-site restoration processing is processing for restoring the transport vehicle 1 with on-site work by the worker 40.

The on-site restoration processing is performed on the condition that the content of the abnormality that has occurred in the transport vehicle 1 is unknown or the importance of the abnormality content is high.

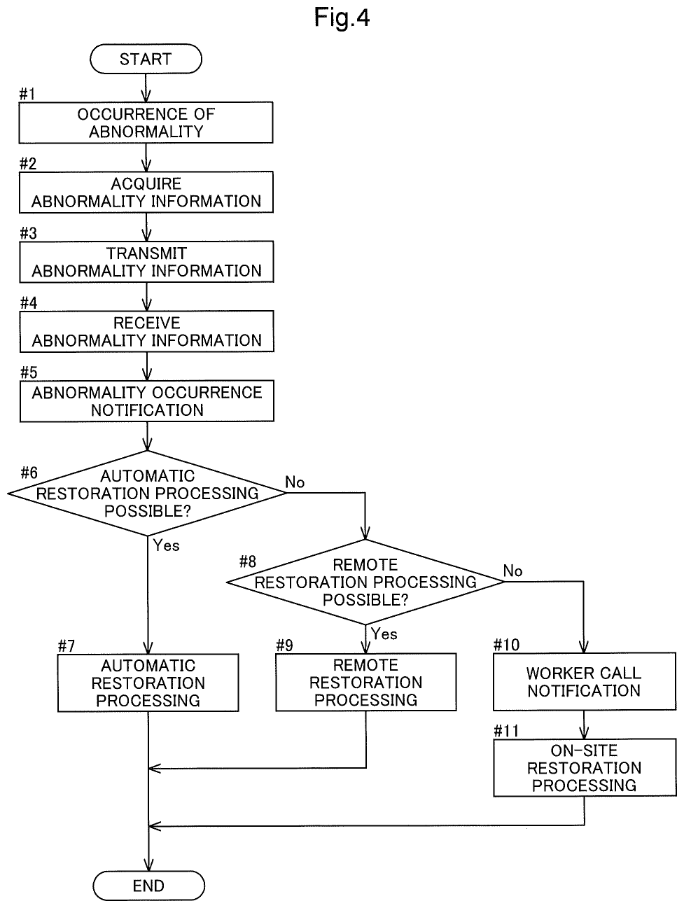

The mobile body 3 in the present embodiment gives the administrator terminal 4 a worker call notification (see also FIG. 4) for calling the worker 40 to the site. In response thereto, the worker 40 heads to the site at which the abnormal transport vehicle 1 is located, and performs work for the restoration processing as appropriate. The on-site restoration processing is executed in this manner. The on-site restoration processing requires the worker 40 to enter the transport room A1 (see FIG. 1) and perform on-site work, which is likely to take time and effort for the worker 40. Meanwhile, the on-site restoration processing has the advantage of being able to have the worker 40 perform highly accurate restoration processing, and of being able to easily respond to events that may occur irregularly.

The mobile body 3 in the present embodiment includes a display device 30 (see also FIG. 2) that displays information, and a display control device 301 that controls the display device 30. In response to the second communication unit 32 receiving the abnormality information I, the display control device 301 generates information indicating at least either the content of the abnormality or the procedure for restoration from the abnormality based on the received abnormality information I, and displays the generated information on the display device 30. The information indicating the content of the abnormality generated by the display control device 301 may be the same as that of the aforementioned abnormality content information included in the abnormality information I, or may be information obtained by altering the abnormality content information for a display purpose. The information indicating the restoration procedure generated by the display control device 301 is information regarding an instruction to the worker 40 who is to perform the restoration work. This configuration allows the worker 40, when executing the on-site restoration processing, to perform the restoration work based on the information displayed on the display device 30. Although detailed illustration is omitted, it is preferable that the mobile body 3 is able to hold a camera for capturing images of the surrounding area of the site, and devices and tools necessary for the on-site restoration work. This allows the worker 40 to properly check the on-site situation and procure the necessary devices and tools for the restoration work on-site. Accordingly, the burden on the worker 40 can be reduced. The mobile body 3 may also receive the item to be transported W from the transport vehicle 1 as needed, either in conjunction with the restoration work or independently of the restoration work. Further, the mobile body 3 may transport the item to be transported W received from the transport vehicle 1 in place of the transport vehicle 1.

FIG. 4 illustrates the procedure that starts when an abnormality occurs and ends when the restoration processing is performed.

As shown in FIG. 4, in response to the occurrence of an abnormality (#1), the information collection device 2 acquires the abnormality information I (#2). The information collection device 2 transmits the abnormality information I to the mobile body 3 (#3). The mobile body 3 receives the abnormality information I from the information collection device 2 (#4) and gives the abnormality occurrence notification N to the administrator terminal 4 (#5).

It is then determined whether the automatic restoration processing is possible (#6), and if it is possible (#6: Yes), the automatic restoration processing is executed (#7). On the other hand, if the automatic restoration processing is not possible (#6: No), it is determined whether the remote restoration processing is possible (#8). If the remote restoration processing is possible (#8: Yes), the remote restoration processing is executed (#9).

On the other hand, if the remote restoration processing is not possible (#8: No), a worker call notification is given (#10). In response thereto, the worker 40 heads to the site of the abnormal transport vehicle 1 and executes the on-site restoration processing (#11).

### Other Embodiments

Next, other embodiments will be described.

(1) In the example of the above embodiment, the abnormality occurrence notification N includes the abnormality content information if the abnormality information I includes the abnormality content information. However, the invention is not limited to this example, and the abnormality occurrence notification N does not necessarily need to include the abnormality content information even if the abnormality information I includes the abnormality content information.

(2) In the example of the above embodiment, the mobile body 3 is configured as a so-called AMR (Autonomous Mobile Robot). However, the invention is not limited to this example, and the mobile body 3 may alternatively be a tracked vehicle, an AGV, a drone, or the like.

(3) In the example of the above embodiment, the transport vehicle 1 is configured as a so-called overhead hoist transport. However, the invention is not limited to this example, and the transport vehicle 1 may alternatively be a tracked vehicle, an AGV (Automatic Guided Vehicle), an AMR (Autonomous Mobile Robot), or the like.

(4) Note that the configurations disclosed in the above embodiments can be combined with configurations disclosed in other embodiments as long as no contradiction arises. Regarding other configurations as well, the embodiments disclosed herein are merely examples in all respects. Therefore, various alterations can be made as appropriate without departing from the gist of the present disclosure.

### Summary of the Present Embodiment

Next, the summary of the present embodiment will be described.

A transport facility includes:
a transport vehicle configured to transport an item to be transported;
an information collection device mounted in the transport vehicle;
a mobile body configured to move separately from the transport vehicle; and
a communication system configured to enable communication between the transport vehicle and a transport control device configured to control the transport vehicle,

wherein the information collection device includes:
an abnormality information acquisition unit configured to acquire, in response to an occurrence of an abnormality in the transport vehicle, abnormality information including at least one of: (i) abnormality content information indicating content of the abnormality; (ii) pre-abnormality occurrence information indicating a state of the transport vehicle before the occurrence of the abnormality; and (iii) post-abnormality occurrence information indicating a state of the transport vehicle after the occurrence of the abnormality; and
a first communication unit configured to transmit the abnormality information, and

the mobile body includes:
a second communication unit configured to communicate with the first communication unit and receive the abnormality information, not via the communication system; and
a third communication unit configured to give an abnormality occurrence notification being a notification of the occurrence of the abnormality, to an administrator terminal capable of being viewed by an administrator administering the transport vehicle.

With this configuration, the mobile body can acquire, in response to the occurrence of an abnormality in a transport vehicle, the abnormality information indicating a cause of the abnormality in the transport vehicle and the state of the transport vehicle before and after the abnormality, and can give the abnormality occurrence notification to the administrator terminal. The administrator can thus quickly ascertain that an abnormality has occurred in the transport vehicle. Further, with this configuration, the mobile body can receive the abnormality information, not via the communication system. Even if communication cannot be performed normally via the communication system due to, for example, the abnormality occurring in the transport vehicle, the abnormality occurrence notification can thus be properly given to the administrator terminal. The administrator can therefore quickly ascertain the abnormality occurring in the transport vehicle regardless of the state of the communication system. As described above, this configuration allows an abnormality in the transport vehicle to be ascertained properly.

It is preferable that the abnormality occurrence notification includes, in addition to information indicating the occurrence of the abnormality, location-related information related to a location where the abnormality has occurred and, if the abnormality information includes the abnormality content information, the abnormality occurrence notification includes the abnormality content information.

With this configuration, the content of the abnormality occurrence notification given to the administrator terminal includes the location-related information and, if the abnormality information includes the abnormality content information, includes the abnormality content information. The administrator can thus quickly ascertain the occurrence of an abnormality in the transport vehicle, as well as information related to the location where the abnormality has occurred. Further, if the abnormality information includes the abnormality content information, the administrator can also quickly ascertain information related to the content of the abnormality that has occurred in the transport vehicle.

It is preferable that the mobile body further includes:
a fourth communication unit configured to communicate with the transport vehicle; and
a command output unit configured to communicate with the transport vehicle via the fourth communication unit and output an operation command to the transport vehicle, and

the operation command includes a restoration operation command for restoring the transport vehicle from an abnormal state.

With this configuration, the mobile body can be used to perform the restoration processing for the abnormal transport vehicle. This can reduce the time and effort for the worker to perform the restoration processing for the abnormal transport vehicle.

It is preferable that the command output unit has an automatic restoration program configured to determine content of the restoration operation command based on the abnormality information received by the second communication unit.

With this configuration, the mobile body can automatically perform the restoration processing for the abnormal transport vehicle. It is thus possible to significantly reduce the time and effort for the worker to perform the restoration processing for the abnormal transport vehicle.

It is preferable that the information collection device includes a power storage device, and is configured to operate even in an absence of a power supply from the transport vehicle.

With this configuration, the information collection device can be operated properly regardless of the content of the abnormality that has occurred in the transport vehicle. Accordingly, in response to an abnormality occurring in the transport vehicle, it is possible to acquire the abnormality information and transmit this abnormality information with high reliability.

It is preferable that the mobile body includes:
a display device configured to display information; and
a display control device configured to control the display device, and

the display control device generates, in response to the second communication unit receiving the abnormality information, information indicating at least either the content of the abnormality or a procedure for restoration from the abnormality, based on the received abnormality information, and causes the display device to display the generated information.

With this configuration, the worker performing restoration work for the transport vehicle in which an abnormality has occurred can check the information displayed on the display device of the mobile body, making it easier for the worker to perform the restoration work.

It is preferable that the transport facility further includes a mobile body control system configured to control the mobile body,

wherein the first communication unit and the second communication unit have a communicable distance therebetween that is shorter than a communicable distance between the transport vehicle and the communication system, and

the mobile body control system causes the mobile body to patrol an area corresponding to a movement route of the transport vehicle.

With this configuration, even if the communicable distance between the mobile body and the transport vehicle is short, it is possible to properly acquire the abnormality information and give the abnormality occurrence notification in response to the occurrence of an abnormality in the transport vehicle. Further, accordingly to this configuration, communication between the first communication unit and the second communication unit, between which the communicable distance is relatively short, can be realized by using, for example, Bluetooth (registered trademark). Thus, power consumption can be reduced compared to the case of using a device that perform long-distance communication such as Wi-Fi (registered trademark) communication.

### Industrial Applicability

The technology according to the present disclosure can be used in a transport facility that includes a transport vehicle configured to transport an item to be transported.

What is claimed is:

1. A transport facility comprising:
a transport vehicle configured to transport an item to be transported;
an information collection device mounted in the transport vehicle;
a mobile body configured to move separately from the transport vehicle; and
a communication system configured to enable communication between the transport vehicle and a transport control device configured to control the transport vehicle,
wherein the information collection device comprises:
an abnormality information acquisition unit configured to acquire, in response to an occurrence of an abnormality in the transport vehicle, abnormality information comprising at least one of: (i) abnormality content information indicating content of the abnormality; (ii) pre-abnormality occurrence information indicating a state of the transport vehicle before the occurrence of the abnormality; and (iii) post-abnormality occurrence information indicating a state of the transport vehicle after the occurrence of the abnormality; and
a first communication unit configured to transmit the abnormality information, and
wherein the mobile body comprises:
a second communication unit configured to communicate with the first communication unit and receive the abnormality information, not via the communication system; and
a third communication unit configured to give an abnormality occurrence notification as a notification of the occurrence of the abnormality, to an administrator terminal capable of being viewed by an administrator administering the transport vehicle.

2. The transport facility according to claim 1,
wherein the abnormality occurrence notification comprises, in addition to information indicating the occurrence of the abnormality, location-related information related to a location where the abnormality has occurred and, if the abnormality information includes the abnormality content information, the abnormality occurrence notification includes the abnormality content information.

3. The transport facility according to claim 1,
wherein the mobile body further comprises:
a fourth communication unit configured to communicate with the transport vehicle; and
a command output unit configured to communicate with the transport vehicle via the fourth communication unit and output an operation command to the transport vehicle, and
wherein the operation command comprises a restoration operation command for restoring the transport vehicle from an abnormal state.

4. The transport facility according to claim 3,
wherein the command output unit has an automatic restoration program configured to determine content of the restoration operation command based on the abnormality information received by the second communication unit.

5. The transport facility according to claim 1,
wherein the information collection device comprises a power storage device, and is configured to operate even in an absence of a power supply from the transport vehicle.

6. The transport facility according to claim 1,
wherein the mobile body comprises:
a display device configured to display information; and
a display control device configured to control the display device, and
wherein the display control device generates, in response to the second communication unit receiving the abnormality information, information indicating at least either the content of the abnormality or a procedure for restoration from the abnormality, based on the received abnormality information, and causes the display device to display the generated information.

7. The transport facility according to claim 1, further comprising:
a mobile body control system configured to control the mobile body,
wherein the first communication unit and the second communication unit have a communicable distance therebetween that is shorter than a communicable distance between the transport vehicle and the communication system, and
wherein the mobile body control system causes the mobile body to patrol an area corresponding to a movement route of the transport vehicle.
